(19) United States
(12) Patent Application Publication
(10) Pub. No.: US 2015/0014864 A1
(43) Pub. Date: Jan. 15, 2015

(54) SEMICONDUCTOR PACKAGE AND METHOD OF FABRICATING THE SAME

(71) Applicant: Siliconware Precision Industries Co., Ltd., Taichung (TW)

(72) Inventors: Wan-Ting Chen, Taichung (TW); Chun-Tang Lin, Taichung (TW); Yi-Che Lai, Taichung (TW)

(73) Assignee: SILICONWARE PRECISION INDUSTRIES CO., LTD., Taichung (TW)

(21) Appl. No.: 14/074,208

(22) Filed: Nov. 7, 2013

(30) Foreign Application Priority Data
Jul. 10, 2013 (TW) 102124672

(51) Int. Cl. H01L 23/28; H01L 21/56

(52) U.S. Cl. CPC H01L 23/28; H01L 21/56
USPC 257/778; 438/108

(57) ABSTRACT

The present invention provides a semiconductor package and a method of fabricating the same. The semiconductor package includes a substrate, a package unit mounted on and electrically connected to the substrate, and a second encapsulant formed on the substrate and encapsulating the package unit. The package unit includes an interposer, a semiconductor chip mounted on the interposer in a flip-chip manner, and a first encapsulant formed on the interposer and encapsulating the semiconductor chip. The present invention reduces the fabricating time and increases the yield of the final product.

### BACKGROUND OF THE INVENTION

1. Field of the Invention

The present invention relates to semiconductor packages and methods of fabricating the same, and, more particularly, to a semiconductor package having an interposer and a method of fabricating the same.

2. Description of the Prior Art

The flip chip technology having the advantages such as minimizing chip area and shortening the signaling pathway has been widely used in chip packaging field, such as chip scale package (CSP), Direct Chip Attached (DCA), and Multi Chip Module (MCM).

However, in a flip-chip fabricating process, the differences of the heat expansion coefficient between the smaller semiconductor chip and circuit substrate is rather large, resulting in a poor connection between the conductive bumps at the periphery of the semiconductor chip and the corresponding electrical points on the circuit substrates, thereby causing the conductive bumps to be easily detached from the substrate.

As the requirement for high density of integrated circuits on the semiconductor chip, the increasing problem associated with thermal stress and warpage resulted from mismatch of heat expansion coefficient between the smaller sized semiconductor chip and the substrate has caused the reliability between the semiconductor chip and the substrate to decrease and resulted failures in reliable tests.

In view of solving the prior problem, a semiconductor package is proposed as shown in FIG. 1. As shown in FIG. 1, through silicon via (TSV) 111 are formed on a piece of silicon wafer, and then a redistribution layer is formed on one side of the silicon wafer where the semiconductor chips are to be mounted, and solder balls 13 are formed on the side where the substrate is to be mounted, then after singulation process where a plurality of interposers 11 are formed, the semiconductor chip 14 each is then mounted to each interposer 11. Subsequently, an underfill encapsulant is formed between the semiconductor chips 14 and the interposers 11. Finally, a plurality of solder balls 19 are formed on the bottom surface of the substrate 16, to finish the fabrication of semiconductor packages with interposers. Since the interposers 11 and the semiconductor chips 14 are made of similar materials, therefore can effectively reduce the problems resulted from mismatch of heat expansion coefficient.

In conventional packages, the width and spacing of the circuits on the substrate can only be as small as 12 μm, when the I/O of the semiconductor chip is increased, it is necessary to increase the substrate area for incorporating more electrical connections.

However in this design, circuits are formed on the one surface where the interposers and semiconductor chips 14 are formed thereon, allowing the electrical connections between the semiconductor chips 14 and the circuits can be formed in silicon wafer fabricating process, such that the width and spacing of the circuits can be 3 μm or lower, allowing a plurality of semiconductor chips 14 to be mounted thereon without increasing the size of the interposers 11.

In addition, in comparison with the conventional technology, wherein the smaller sized semiconductor chip is directly mounted on the substrate, the foregoing interposer 11 functions as a breakout board, therefore the width and spacing of the circuits on the interposer is the similar to that of semiconductor chip 14, allowing the semiconductor chip with high I/O to be mounted to the interposer, thereby minimizing the overall package of the semiconductor package, increasing the overall electrical transmission speed.

Conventionally, in order to meet the requirement of high I/O numbers of the semiconductor chip, multi-layered redistribution layer (RDL) is required to be formed on the surface of the interposer 11 where semiconductor chips are mounted thereon, for providing a plurality of electrical connections between the semiconductor chips and providing fan out for the electrode pads of the semiconductor chips. For examples, if a semiconductor chip as 1000 electrical connections, after fan out there are 800 electrical connections electrically connected to the interposer and the remaining 200 electrical connection points on the semiconductor chip can be used for providing electrical connection between semiconductor chips. Moreover, as the width and spacing of the circuit of the substrate is larger than that of the electrode pads of the semiconductor chip, therefore the number of layers of distributed circuits formed on surface (defined as the back surface) of the interposer mounted to the substrate will be smaller than that on the front surface thereof, or without the need of forming circuit redistribution layers.

According to CoC or Cos fabricating process developed from 3D-IC nowadays, interposers must underwent a die saw process to select known good die (KGD) for the subsequent encapsulating process, as a result it is easy to produce fragments during the mechanical cutting of the interposers having redistribution layers on both side. Moreover, since the stacking process in CoWoS, requires multiple high temperature fabricating processes and also a final encapsulant before testing, it is difficult to reduce the overall production cost.

### SUMMARY OF THE INVENTION

In light of the foregoing drawbacks of the prior art, the present invention proposes a semiconductor package, comprising a substrate, a package unit mounted on and electrically connected to the substrate, and a second encapsulant formed on the substrate and encapsulating the package unit, wherein the package unit comprises an interposer, a semiconductor chip mounted on the interposer in a flip-chip manner, and a first encapsulant formed on the interposer and encapsulating the semiconductor chip.

In an embodiment, the semiconductor chip has a surface in no contact with the interposer that is exposed to top surfaces of the first encapsulant and the second encapsulant.

In an embodiment, the semiconductor chip has passed a die test, and a redistribution layer is formed on at least one surface of the interposer.

In an embodiment, the first encapsulant has a side surface flush with a side surface of the interposer, and the second encapsulant has a side surface flush with a side surface of the substrate.

The present invention further proposes a method of fabricating a semiconductor package, comprising: mounting a plurality of semiconductor chips on an interposer in a flip-chip manner; forming on the interposer a first encapsulant that encapsulates the semiconductor chip; performing a first singulation process to form a plurality of package units; mounting and electrically connected the package units to a substrate; and forming on the substrate a second encapsulant that encapsulates the package units.

In an embodiment, the method further comprises performing a second singulation process after the second encapsulant is formed, allowing a surface of the semiconductor chip that is in no contact with the interposer is exposed to a top surface of the first encapsulant.

In an embodiment, the semiconductor chip has a surface in no contact with the interposer that is exposed to a top surface of the second encapsulant.

In an embodiment, the semiconductor chip has passed a die test, and a redistribution layer is formed on at least one surface of the interposer.

In an embodiment, the surface of the semiconductor chip is exposed by a grounding process.

In summary, the present invention utilizes one time encapsulating process to replace multiple underfill processes, allowing the overall fabricating process to be simplified. Besides, the singulation process is performed after the encapsulant is formed, to prevent generating material fragments resulted from cutting the interposer or the problem of detachment of the semiconductor chip from the interposer. Moreover, through die test to select known good die (KGD), the yield of the final semiconductor package can be desirably improved.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a conventional semiconductor package; and

FIGS. 2A-2E are cross-sectional views of a semiconductor package and a method of fabricating the same according to the present invention, wherein FIG. 2B′ represents another embodiment of FIG. 2B, and FIG. 2D′ is another embodiment of FIG. 2D.

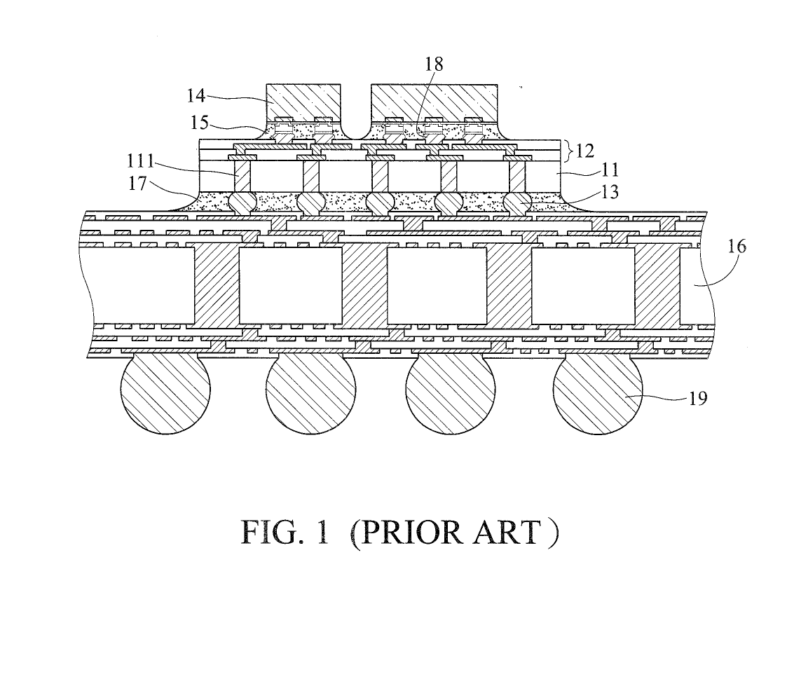

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the present invention.

It is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements. In addition, words, such as “on”, “top” and “a”, are used to explain the preferred embodiment of the present invention only and should not limit the scope of the present invention.

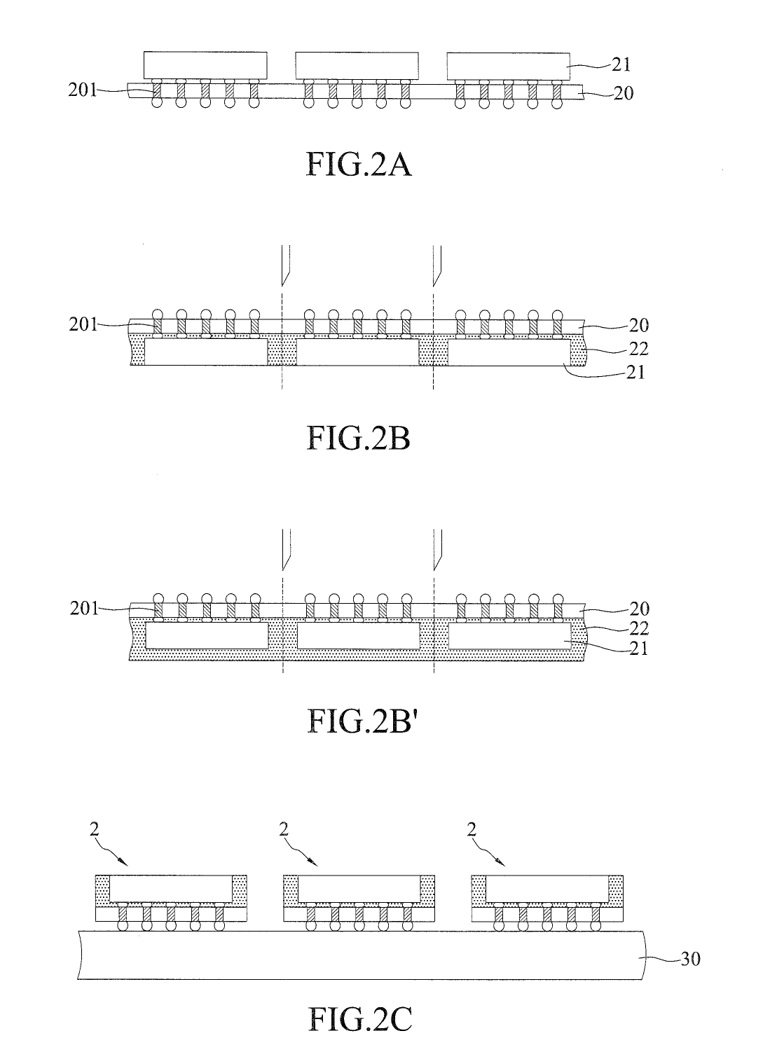

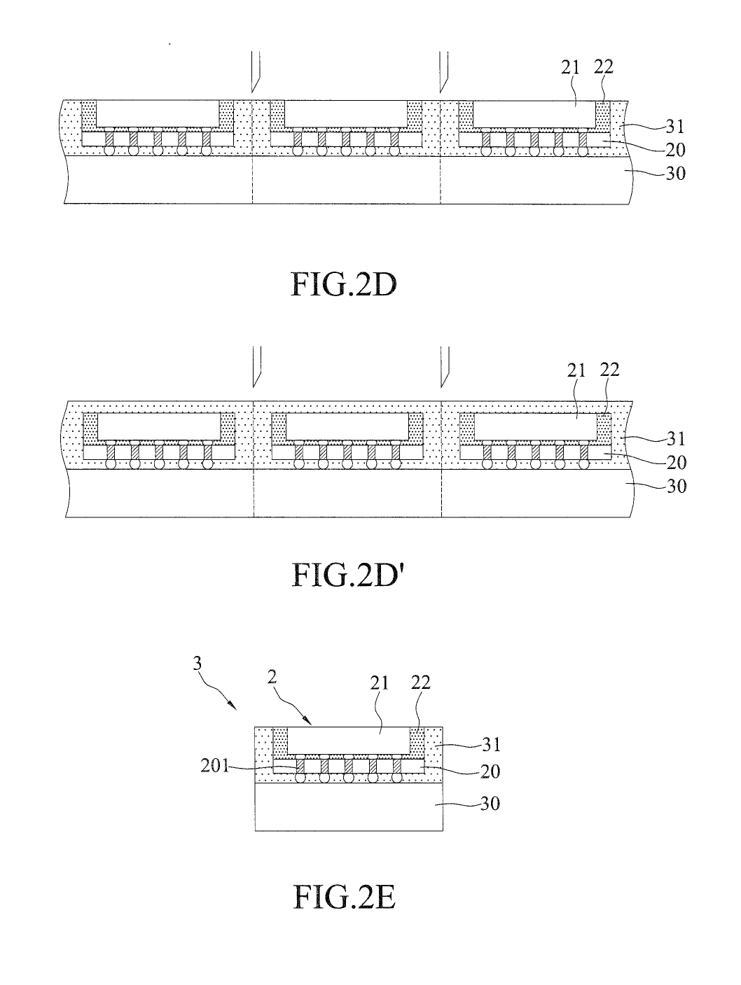

FIGS. 2A-2E are cross-sectional views of a semiconductor package and a method of fabricating the same according to the present invention, wherein FIG. 2B′ represents another embodiment of FIG. 2B, and FIG. 2D′ is another embodiment of FIG. 2D.

As shown in FIG. 2A, a plurality of semiconductor chips 21 are mounted on an interposer 20, each of the semiconductor chips 21 is a known good die (KGD), and the interposer 20 has a plurality of conductive vias 201 penetrating through the two surfaces thereof. Redistribution layers can be selectively formed on at least one surface of the interposer 20 (not shown).

As shown in FIG. 2B, a first encapsulant 22 is formed on the interposer 20 and encapsulates the semiconductor chips, allowing the surface (non-active surface) of the semiconductor chip 21 that is in no contact with the interposer to be exposed to the top surface of the first encapsulant 22. In such a way, the exposed non-active surface of the semiconductor chip 21 allows the molding equipment of the first encapsulant 22 to abut against the non-active surface of the semiconductor chip, or a first encapsulant 22 is formed to cover the non-active surface of the semiconductor chip 21 (as shown in FIG. 2B′), followed by a grounding process to remove the first encapsulant 22 on the non-active surface of the semiconductor chip 21. Then, a singulation process is performed to form a plurality of package units 2.

Alternatively, as shown in FIG. 2B′, the first singulation process is performed after the encapsulant 22 encapsulates the non-active surface of the semiconductor chip 21. The subsequent steps are described in FIG. 2B.

As shown in FIG. 2C, the package unit 2 is mounted on and electrically connected to a substrate 30. In an embodiment, the substrate 30 is in the shape of a strip.

As shown in FIG. 2D, a second encapsulant 31 is formed on the substrate 30 to encapsulate the package unit 2, allowing the surface (non-active surface) of the semiconductor chip 21 that is in no contact with the interposer to be exposed to the top surface of the second encapsulant 31. In such a way, the exposed non-active surface of the semiconductor chip 21 allows the molding equipment of the second encapsulant 31 to abut against the non-active surface of the semiconductor chip, or a second encapsulant 31 is formed to encapsulate the non-active surface of the semiconductor chip 21 (as shown in FIG. 2B′), followed by a grounding process to remove the first encapsulant 31 on the non-active surface of the semiconductor chip 21. Then, a second singulation process is performed to form a plurality of semiconductor package 3 shown in FIG. 2E.

Alternatively, as shown in FIG. 2D′, a second singulation process is performed after the non-active surface of the semiconductor chip 21 is encapsulated by the second encapsulant 31.

A semiconductor package disclosed according to the present invention further comprises a substrate 30, a package unit 2 mounted on and electrically connected to the substrate 30, and a second encapsulant 31 formed on the substrate 30 to encapsulate the package unit 2, wherein the package unit 2 comprises an interposer 20, a semiconductor die 21 mounted on the interposer 20 in a flip chip manner, and a first encapsulant 22 formed on the interposer 20 to encapsulate the semiconductor die 21.

In an embodiment, the surface of the semiconductor chip that is in no contact with the interposer is exposed to the top surfaces of the first encapsulant 22 and the second encapsulant 31.

In an embodiment, the semiconductor chip is a known good die (KGD) and a redistribution layer is formed on at least one surface of the interposer.

In an embodiment, the side surface of the first encapsulant 22 is flush with the side surface of the interposer 20, and the side surface of the second encapsulant 31 is flush with the side surface of the substrate 30.

It should be noted that the first encapsulant and second encapsulant selectively encapsulate or do not encapsulate the non-active surface of the semiconductor die. FIG. 2E is provided to explain a preferred embodiment, the claims of the present invention are not limited by this preferred embodiment.

In summary, the present invention utilizes one time encapsulating process to replace multiple underfill processes, allowing the overall fabricating process to be simplified. Besides, the singulation process is performed after the encapsulant is formed, to prevent generating material fragments resulted from cutting the interposer or the problem of detachment of the semiconductor chip from the interposer. Moreover, through die test to select known good die (KGD), the yield of the final semiconductor package can be desirably improved.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor package, comprising:
a substrate;
a package unit, mounted on and electrically connected to the substrate, comprising:
an interposer;
a semiconductor chip mounted on the interposer in a flip-chip manner;
a first encapsulant formed on the interposer and encapsulating the semiconductor chip; and
a second encapsulant formed on the substrate and encapsulating the package unit.

2. The semiconductor package of claim 1, wherein the semiconductor chip has a surface in no contact with the interposer that is exposed to a top surface of the first encapsulant.

3. The semiconductor package of claim 2, wherein the surface of the semiconductor chip is exposed to a top surface of the second encapsulant.

4. The semiconductor package of claim 1, wherein the semiconductor chip has passed a die test.

5. The semiconductor package of claim 1, wherein the interposer has a redistribution layer formed on at least one surface thereof.

6. The semiconductor package of claim 1, wherein the first encapsulant has a side surface flush with a side surface of the interposer.

7. The semiconductor package, of claim 1, wherein the second encapsulant has a side surface flush with a side surface of the substrate.

8. A method of fabricating a semiconductor package, comprising:
mounting a plurality of semiconductor chips on an interposer in a flip-chip manner;
forming on the interposer a first encapsulant that encapsulates the semiconductor chip;
performing a first singulation process to form a plurality of package units;
mounting and electrically connected the package units to a substrate; and
forming on the substrate a second encapsulant that encapsulates the package units.

9. The method of claim 8, further comprising performing a second singulation process after the second encapsulant is formed.

10. The method of claim 8, wherein the semiconductor chip has a surface in no contact with the interposer that is exposed to a top surface of the first encapsulant.

11. The method of claim 10, wherein the surface of the semiconductor chip is exposed by a grounding process.

12. The method of claim 10, wherein the surface of the semiconductor chip is exposed to a top surface of the second encapsulant.

13. The method of claim 12, wherein the surface of the semiconductor chip is exposed by a grounding process.

14. The method of claim 8, wherein the semiconductor chip has passed a die test.

15. The method claim 8, wherein the interposer has a redistribution layer formed on at least one surface thereof.
